(19) United States
(12) Patent Application Publication
(10) Pub. No.: US 2023/0137512 A1
(43) Pub. Date: May 4, 2023

(54) STACKED SSD SEMICONDUCTOR DEVICE

(71) Applicant: WESTERN DIGITAL TECHNOLOGIES, INC., San Jose, CA (US)

(72) Inventors: Hui Xu, Shanghai (CN); Kim Lee Bock, Sengalor (MY); Rama Shukla, Saratoga, CA (US); Chong Un Tan, Shanghai (CN); Yoong Tatt Chin, Penang (MY); Shrikar Bhagath, San Jose, CA (US)

(73) Assignee: WESTERN DIGITAL TECHNOLOGIES, INC., San Jose, CA (US)

(21) Appl. No.: 17/517,911

(22) Filed: Nov. 3, 2021

(51) Int. Cl. H05K 1/02; H05K 1/11

(52) U.S. Cl. CPC H05K 1/0203; H05K 1/117; H05K 1/0218; H05K 2201/10159

(57) ABSTRACT

A semiconductor memory device, also referred to as a solid state drive, includes thermally conductive components such as a conductive coating to draw heat away from the semiconductive package. The coating may also be electrically conductive to provide shielding from and absorption of electromagnetic interference. In examples, a semiconductor device including a substrate may be affixed to an edge connector printed circuit board with solder balls to form a solid state drive. In further examples, the substrate may be omitted, and semiconductor memory dies, a controller die and other electronic components may be directly surface mounted to an edge connector printed circuit board to form a solid state drive.

### BACKGROUND

The strong growth in demand for portable consumer electronics is driving the need for high-capacity storage devices. Non-volatile semiconductor memory devices are becoming widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, SSDs (solid state drives), PDAs and cellular telephones.

While many varied packaging configurations are known, flash memory semiconductor devices may in general be assembled as system-in-a-package (SIP) or multichip modules (MCM), where a plurality of semiconductor die are mounted and interconnected to an upper surface of a small footprint substrate. The substrate may in general include a rigid, dielectric base having a conductive layer etched into a pattern of pads and traces on one or both sides. One or more semiconductor memory dies and a controller die are then mounted and electrically coupled to the substrate, and the dies are then encapsulated in a mold compound.

Designers of semiconductor packages currently face several challenges. As semiconductor packages get smaller and operate at higher frequencies, heat generated by the controller die can become a significant issue, as heat can impair operation of the semiconductor package. Additionally, semiconductor packages are currently used in a wide variety of applications, from LGA memory cards to BGA solid state drives. It would be advantageous to provide a semiconductor package design that is scalable for use with various numbers of semiconductor dies and adaptable for use in a variety of applications, including solid state drives.

### DESCRIPTION OF THE DRAWINGS

FIG. 1 is a flowchart of the overall fabrication process of a substrate and a semiconductor device using that substrate according to embodiments of the present technology.

FIG. 2 is a top view of a panel of substrates according to an embodiment of the present technology.

FIG. 3 is a top view of a substrate of a semiconductor device at a first step in the assembly process according to an embodiment of the present technology.

FIG. 4A is a bottom view of a substrate of a semiconductor device at a first step in the assembly process according to an embodiment of the present technology.

FIG. 4B is a bottom view of a substrate of a semiconductor device at a first step in the assembly process according to an alternative embodiment of the present technology.

FIG. 5 is a side view of a number of memory dies mounted on a substrate according to embodiments of the present technology.

FIG. 6 is a side view of a number of memory dies, a controller die and a heat spreader block mounted on a substrate according to embodiments of the present technology.

FIG. 7 is a side view of a number of memory dies wire bonded to a substrate according to embodiments of the present technology.

FIG. 8 is a side view of an encapsulated semiconductor device according to embodiments of the present technology.

FIG. 9 is a side view of an encapsulated semiconductor device with the heat spreader block exposed at a surface of the device according to embodiments of the present technology.

FIGS. 10 and 11 are side and perspective views, respectively, of an encapsulated semiconductor device with a thermally conductive coating according to embodiments of the present technology.

FIG. 12 is a side view an encapsulated semiconductor device with a thermally conductive coating according to an alternative embodiment of the present technology.

FIG. 13 is a side view of a semiconductor device according to embodiments of the present technology configured as an LGA package.

FIG. 14 is a top view of an LGA semiconductor device according to embodiments of the present technology used within a memory card.

FIG. 15 is a side view of a semiconductor device according to embodiments of the present technology configured as a BGA package mounted to a host device such as a PCB.

FIG. 16 is a side view of multiple BGA semiconductor devices according to embodiments of the present technology mounted to a first surface of a host device such as a PCB.

FIG. 17 is a side view of multiple BGA semiconductor devices according to embodiments of the present technology mounted to first and second opposed surfaces of a host device such as a PCB.

FIG. 18 is a top view of a BGA semiconductor device according to embodiments of the present technology configured within a USB memory storage device.

FIG. 19 is a top view of a BGA semiconductor device according to embodiments of the present technology configured within an SSD on an edge connector card.

FIG. 20 is a top view of BGA semiconductor devices according to embodiments of the present technology configured within a further example of an SSD.

FIGS. 21-23 are side views of various configurations of a host device including semiconductor devices with various numbers of memory dies.

FIGS. 24-26 are side and top views of an SSD edge connector card according to embodiments of the present technology.

### DETAILED DESCRIPTION

The present technology will now be described with reference to the figures, which in embodiments, relate to a semiconductor memory device including thermally conductive components including a conductive coating to draw heat away from the semiconductive package. The coating may also be electrically conductive to provide shielding from and absorption of electromagnetic interference. The semiconductor device of the present technology may be fabricated in different configurations. In one example, the semiconductor device may be configured as an LGA (land grid array) device and packaged as a memory card. In a further example, the semiconductor device may be configured as a BGA (ball grid array) device mounted on a printed circuit board. The BGA device may then be used as a USB drive, or mounted to a motherboard by an edge connector.

In embodiments, a semiconductor device including a substrate may be affixed to an edge connector printed circuit board as by solder balls to form a solid state drive. In further embodiments, the substrate may be omitted, and semiconductor memory dies, a controller die and other electronic components may be directly surface mounted to an edge connector printed circuit board to form a solid state drive.

The semiconductor memory device may be easily scaled or adapted with storage capacities tailored to different applications, for example using different numbers of flash memory dies and/or random access memory dies. The semiconductor memory device of the present technology provides further advantages of simplified manufacturing assembly and testing procedures.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

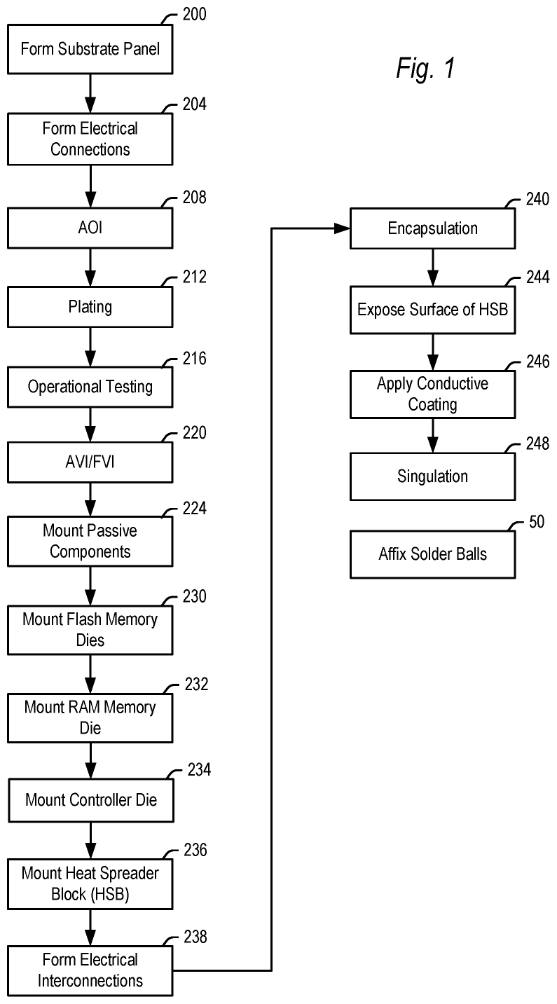

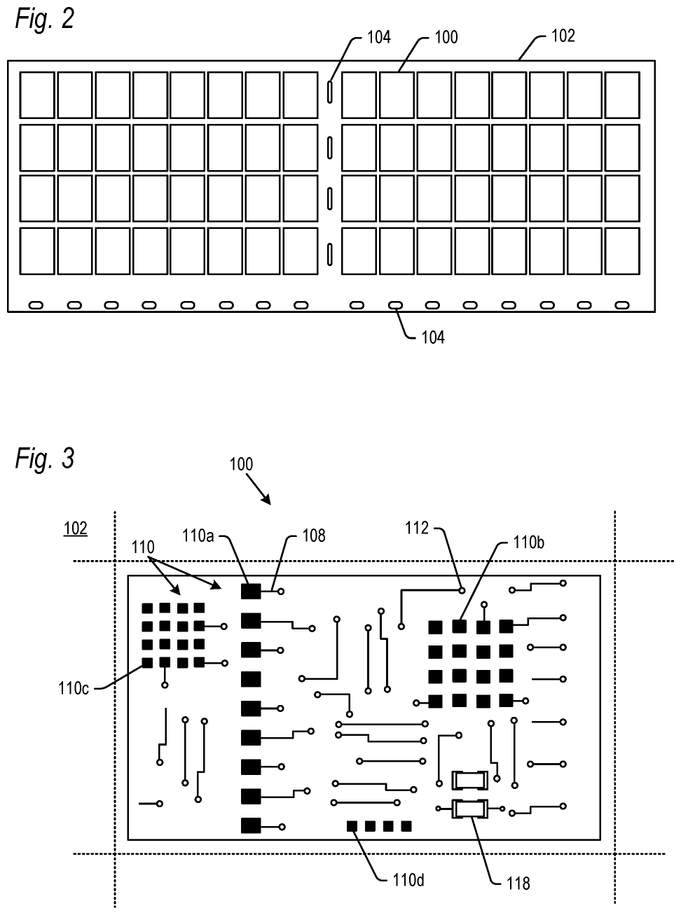

An embodiment of the present technology will now be explained with reference to the flowchart of FIG. 1 and the top, side and perspective views of FIGS. 2 through 26. The assembly of semiconductor device 150 begins with a plurality of substrates 100 formed contiguously on a panel 102 in step 200 as shown in FIG. 2. FIG. 2 shows one representation of a panel 102 of substrate 100, though panel 102 may have a wide variety of other configurations and numbers of substrates 100 in further embodiments. Fiducial marks 104 are provided on the substrate panel 102 to allow machine vision alignment of the substrate panel in a processing tool. Again, the fiducial marks are by way of example only and may vary in other substrate panels.

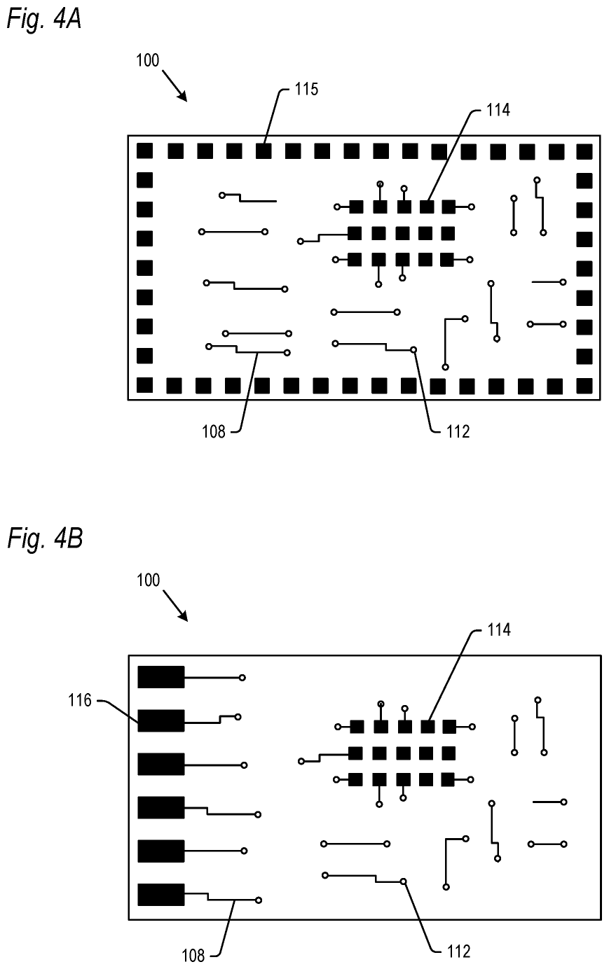

The substrate 100 is shown in FIGS. 3-4B. The substrate 100 is an example of a chip carrier medium provided to transfer signals, data and/or information between one or more dies mounted on the chip carrier medium and a host device as explained below. However, it is understood that other examples of chip carrier mediums may be used, including a printed circuit board (PCB), a leadframe or a tape automated bonded (TAB) tape. The example where the chip carrier medium is a PCB is explained below. Where substrate 100 is a substrate, the substrate may be formed of one or more core layers, each sandwiched between two conductive layers. The one or more core layers may be formed of various dielectric materials such as for example, polyimide laminates, epoxy resins including FR4 and FR5, bismaleimide triazine (BT), and the like. The one or more core layers may be ceramic or organic in alternative embodiments.

In step 204, the two or more conductive layers may be etched into conductance patterns comprising electrical connectors. The electrical connectors may include electrical traces 108, contact pads 110, and through-hole vias 112 electrically interconnecting conductance patterns of the different conductive layers of substrate 100. The conductance pattern shown in FIG. 3 is by way of example only and may vary in further embodiments. Where the substrate 100 includes internal conductive layers (between the external upper and lower conductive layers), the conductance patterns in the one or more of the internal conductive layers may be formed before the layer is assembled into the substrate 100. The conductance patterns in the various layers may be formed by photolithography, screen printing and other methods.

While various patterns of electrical connectors may be provided, in one embodiment, the electrical connectors may comprise contact pads for physically and electrically attaching different components. These contact pads may include contact pads 110a for affixing flash memory dies, contact pads 110b for affixing a controller die, and contact pads 110c for affixing dynamic RAM, as explained below. Contact pads 110c may be omitted in further embodiments. Contact pads 110 further include grounded contact pads 110d for connecting to a device cover for EMI/RFI shielding of the semiconductor device 150 as explained below. The number of contact pads 110a, 110b, 100c and/or 110d (referred to generally as contact pads 110) are by way of example, and may vary in further embodiments. The contact pads 110, and the electrical connectors in general, may be formed of a variety of materials such as copper, copper alloys, plated copper alloys, Alloy 42 (42Fe/58Ni), or other metals and materials.

FIGS. 4A and 4B are bottom views of two alternative embodiments of the bottom surface of substrate 100. Both embodiments include test pads 114 enabling testing of the semiconductor device 150 upon completion and/or during assembly as explained below. The embodiment of FIG. 4A may be configured as a BGA (ball grid array) device including solder ball pads 115 for receiving solder balls as explained below. The solder ball pads and solder balls allow the completed semiconductor device 150 to physically and electrically mount to a host device such as a printed circuit board. The number and pattern of solder ball pads 115 is by way of example only and may vary in further examples. The embodiment of FIG. 4B is configured as an LGA (land grid array) device including contact fingers 116. The contact fingers 116 enable the completed semiconductor device 150 to be removably inserted into a slot of a host device such as a mobile phone, laptop or other computing device. The number and pattern of contact fingers 116 is by way of example only and may vary in further examples.

Referring again to FIG. 1, the substrate 100 may next be inspected in step 208, for example in an automatic optical inspection (AOI). Once inspected, the contact pads 110 may be plated in step 212, for example, with a Ni/Au, Alloy 42, or the like, in a known electroplating or thin film deposition process. The substrate 100 may next undergo operational testing in step 216 to ensure the substrate 100 is working properly. In step 220, the substrate may be visually inspected, including for example an automated visual inspection (AVI) and a final visual inspection (FVI) to check for contamination, scratches and discoloration. One or more of these steps may be omitted or performed in a different order in further embodiments. For example, as explained below, in one embodiment, an SSD is formed by mounting dies and other electronic components directly onto an edge connector PCB. In such an embodiment, the inspection steps 208 and 220 may be omitted, and the operational testing step 216 may be omitted.

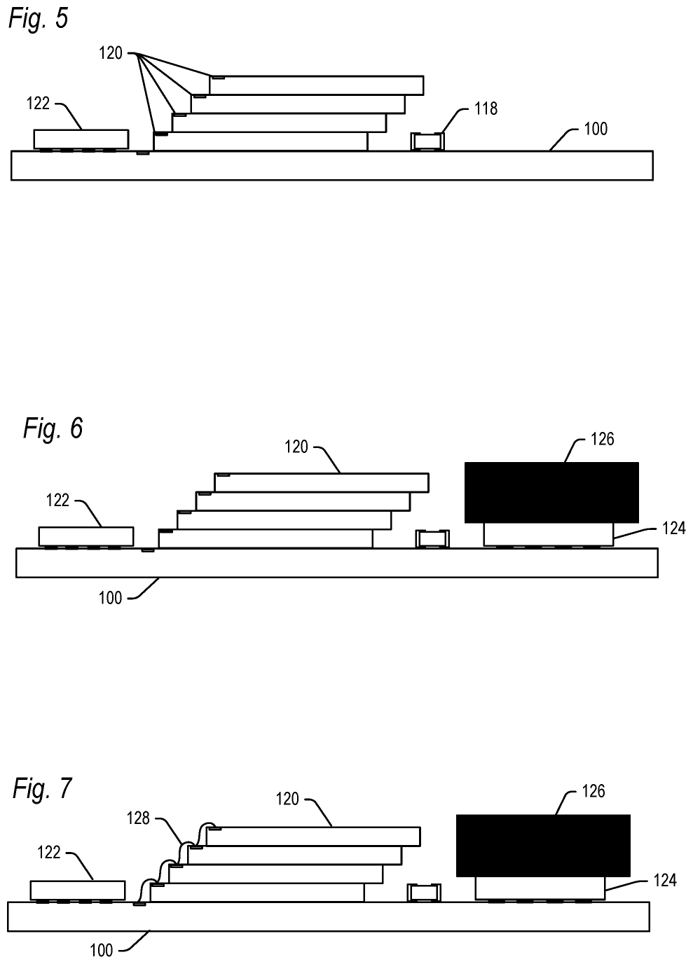

Assuming the substrate 100 passes inspection, passive components 118 (FIGS. 3 and 5) may next be affixed to the substrate 100 in a step 224. The one or more passive components may include for example one or more capacitors, resistors and/or inductors, though other components are contemplated. The passive components 118 shown are by way of example only, and the number, type and position may vary in further embodiments.

In step 230, one or more semiconductor dies 120 may be mounted on the substrate 100, as shown in the side view of FIG. 5. The semiconductor dies 120 may for example include memory dies such as 2D NAND flash memory or 3D BiCS (Bit Cost Scaling), V-NAND or other 3D flash memory, but other types of dies 120 may be used. Where multiple semiconductor dies 120 are included, the semiconductor dies 120 may be stacked atop each other in an offset stepped configuration to form a die stack as shown. The number of dies 120 shown in the stack is by way of example only, and embodiments may include different numbers of semiconductor dies, including for example 1, 2, 4, 8, 16, 32 or 64 dies. There may be other numbers of dies in further embodiments and the stacking does not have to be in the offset arrangement shown. The dies 120 may be affixed to the substrate and/or each other using a die attach film. As one example, the die attach film may be cured to a B-stage to preliminarily affix the dies 120 in the stack, and subsequently cured to a final C-stage to permanently affix the dies 120 to the substrate 100.

Optionally, adding the memory dies may include surface mounting a RAM (random access memory) die 122 onto the substrate 100 in step 232. The RAM die 122 may for example be SDRAM, DDR SDRAM, LPDDR and/or GDDR. The RAM die 122 may be omitted in further embodiments. Where included, the RAM die 122 may be flip-chip mounted to pads 110c.

In step 234, a controller die 124 may additionally be mounted to the substrate as shown in FIG. 6. Controller die 124 may for example be an ASIC for controlling the transfer of signals and data to and from the memory dies 120 and RAM die 122. The controller die 124 may be flip-chip mounted to pads 110b.

As indicated in the Background section, the controller die 124 may disadvantageously generate heat. In order to conduct heat away from the controller die, a head spreader block (HSB) 126 may be affixed on top of the controller die in step 236. The HSB 126 may be formed of a variety of thermally conductive materials, including metals such as copper and aluminum. It may be made of other materials including silicon. HSB 126 may have a length and width at least as large as the length and width of the controller die 124, but the length and/or width of the HSB 126 may be greater or smaller than the length and/or width of the controller die 124 in further embodiments. The height of the HSB 126 may extend to be flush with, or slightly below, the eventual upper surface of the mold compound encapsulating the semiconductor dies as explained below. The HSB 126 may be affixed to an upper surface of the controller die 124 using any of various thermally conductive adhesives.

In step 238, the semiconductor dies 120 may be electrically interconnected to each other and to contact pads 110a on the substrate 100. FIG. 7 shows a side view of bond wires 128 being formed between corresponding die bond pads on respective dies 120 down the stack, and then bonded to contact pads 110a on the upper surface of the substrate 100. The wire bonds may be formed using known techniques and wire bonding machines, such as by a ball-bonding technique, where a wire bond capillary (not shown) applies a ball bump onto a contact pad 110a, and thereafter pays out wire to make a stitch bond at the next die bond pad. Other wire bonding techniques are possible. The semiconductor dies 120 may be electrically interconnected to each other and the substrate 100 by other methods in further embodiments, including by through-silicon vias (TSVs) and flip-chip technologies.

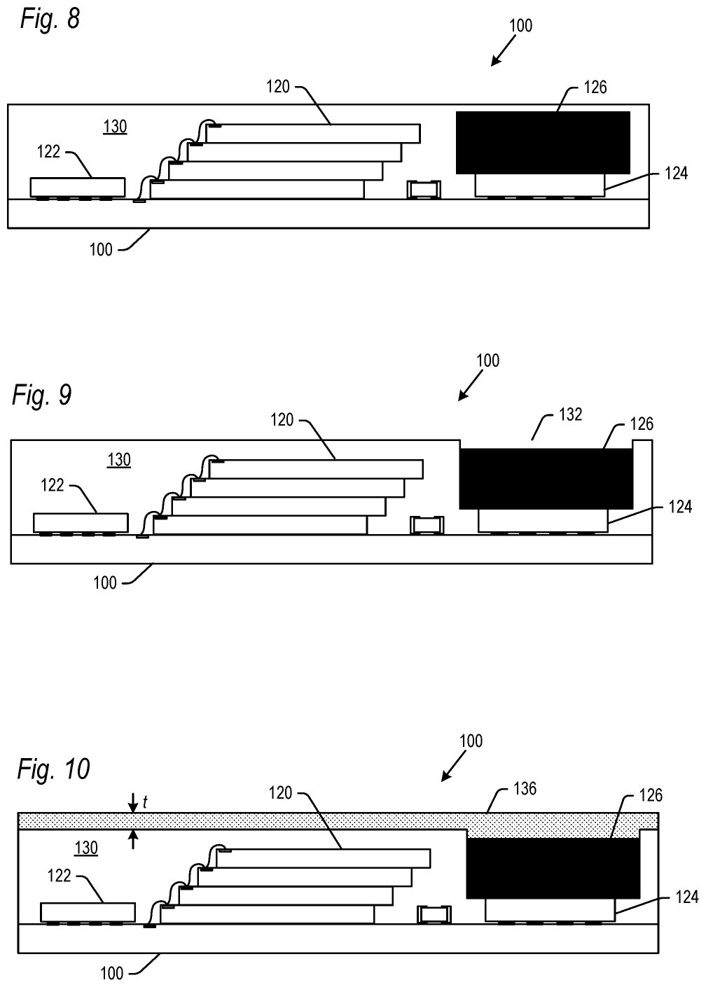

Following formation of electrical interconnection of the dies 120 to the substrate 100, the semiconductor device 150 may be housed within an enclosure in a step 240 as shown in the side view of FIG. 8. The enclosure may be a mold compound 130 encapsulating the semiconductor dies, bond wires 128 and other components on substrate 100. The mold compound 130 may include for example solid epoxy resin, Phenol resin, fused silica, crystalline silica, carbon black and/or metal hydroxide. Other mold compounds are contemplated. The mold compound may be applied by various known processes, including by compression molding, transfer molding or injection molding techniques. The semiconductor devices 150 may be encapsulated by other methods including FFT (flow free thin) molding. As noted above, an upper surface of the HSB 126 may lie in the plane of an upper surface of mold compound 130, or slightly below it.

In accordance with aspects of the present technology, a thermally conductive coating may be applied over at least an upper surface of semiconductor device 150, which conductive coating lies in contact with an upper surface of HSB 126. In embodiments, the upper surface of HSB 126 may lie slightly below an upper planar surface of mold compound 130. In such embodiments, the mold compound may be removed above the HSB 126 in step 244 to create a recess 132 into a plane of the upper surface of the mold compound, as shown in the side view of FIG. 9. The mold compound above HSB 126 may be removed by a variety of methods including by laser, chemical etching or grinding.

The thermally conductive coating 136 may be applied over at least the upper surface of semiconductor device 150 in step 246 as shown in the side view of FIG. 10. The thermally conductive coating 136 fills recess 132 and lies in contact with an upper surface of the HSB 126. The thermally conductive coating 136 may also be applied to a thickness, t, above a surface of the mold compound 130. In examples, the thickness, t, may be 5 to 20 μm, though it may be thinner or thicker than that in further embodiments. In one such embodiment, the thickness, t, may be zero, with the conductive coating 136 applied only into recess132 over the HSB 126.

The thermally conductive coating 136 may be formed of a variety of thermally conductive films, including for example Graphene, Silicon Carbide, CNT(Carbon nanotube), carbon nanomaterials and other metals or alloys having high thermal conductivity. The thermally conductive coating 136 may be applied to an upper surface of the semiconductor device by a variety of methods including by painting, printing, sputtering, plating or thin film deposition techniques such as PVD (Physical Vapor Deposition) or CVD (Chemical Vapor Deposition). In embodiments, in addition to being thermally conductive, the coating 136 may be electrically conductive to provide EMI/RFI shielding and/or absorption as described below.

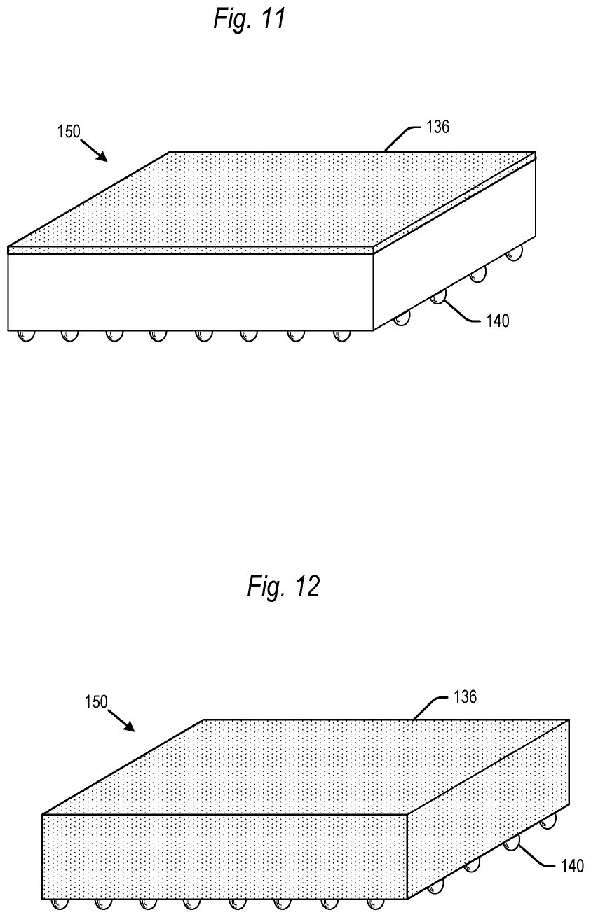

At this stage in the assembly, the individual semiconductor devices 150 are still part of panel 102 so the thermally conductive coating 136 may be applied over the entire surface of the panel 102. Once the thermally conductive coating 136 is applied, the individual semiconductor devices 150 may be singulated from the panel 102 in step 248 and as shown for example in the perspective views of FIGS. 11 and 12. The individual semiconductor devices may be singulated from panel 102 using any of a variety of cutting methods including by saw blade, laser, waterjet or other methods.

FIGS. 11 and 12 are perspective views of a completed semiconductor device 150. As noted above, the thermally conductive coating 136 may be applied over the entire surface of the substrate panel 102, so that, once singulated, the coating 136 is on an upper surface of the semiconductor device 150 as shown in FIG. 11. In such embodiments, heat from the controller die is conducted from the controller 124 to the HSB 126, and from the HSB 126 to the conductive coating 136, where it is radiated from an upper surface of the semiconductor device 150 to the ambient environment surrounding the device 150. In further embodiments, after singulation, the coating 136 may also be applied to one or more side edges of the semiconductor device 150 as shown in FIG. 12. Provision of the coating 136 on the one or more side edges may further enhance heat dissipation from the semiconductor device 150.

As note above, in embodiments, the completed semiconductor device 150 may be used as a BGA package, affixed to a host device such as a printed circuit board. For such embodiments, solder balls 140 may be affixed to contact pads 115 (FIG. 4A) on a lower surface of the substrate 100 in step 240 and as shown in FIGS. 11 and 12 for use in soldering the semiconductor device 150 to the host device.

While the flowchart of FIG. 1 illustrates a certain order of assembly steps, it is understood that at least some of steps in FIG. 1 may be performed in a different order than shown. For example, the solder balls 140 may be applied at an earlier stage in device assembly, such as before singulation. The dies 120, 122 and 124 may also be applied in different orders, and electrically connected to the substrate in different orders. As noted above, certain assembly steps may also be omitted in further embodiments.

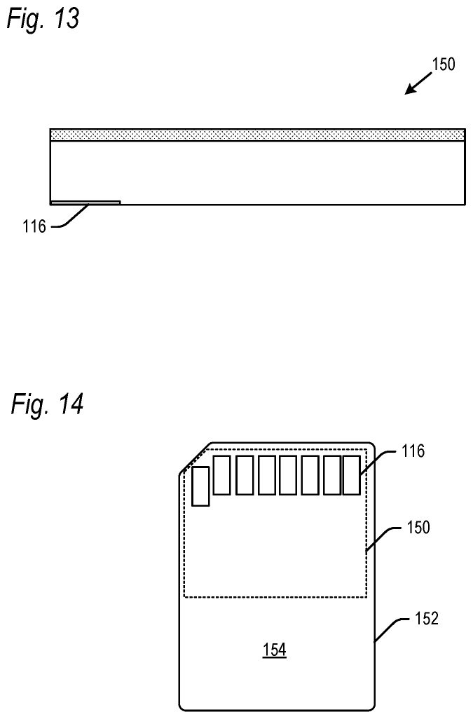

Semiconductor device 150 may be configured as BGA package with solder balls 140, or an LGA package where solder balls 140 are omitted. FIGS. 13 and 14 are edge and bottom views, respectively, of an example where device 150 is configured as an LGA package. In such embodiments, the semiconductor device 150 may be sealed within a plastic housing 152 and used as a memory card 154 according to any of a wide variety of standard and non-standard formats. The memory card 154 including the semiconductor device 150 may be removably inserted within a slot of a host device, with contact fingers 116 (FIGS. 4B and 14) connecting with pins within the slot of the host device to enable exchange of data between the semiconductor device 150 and host device.

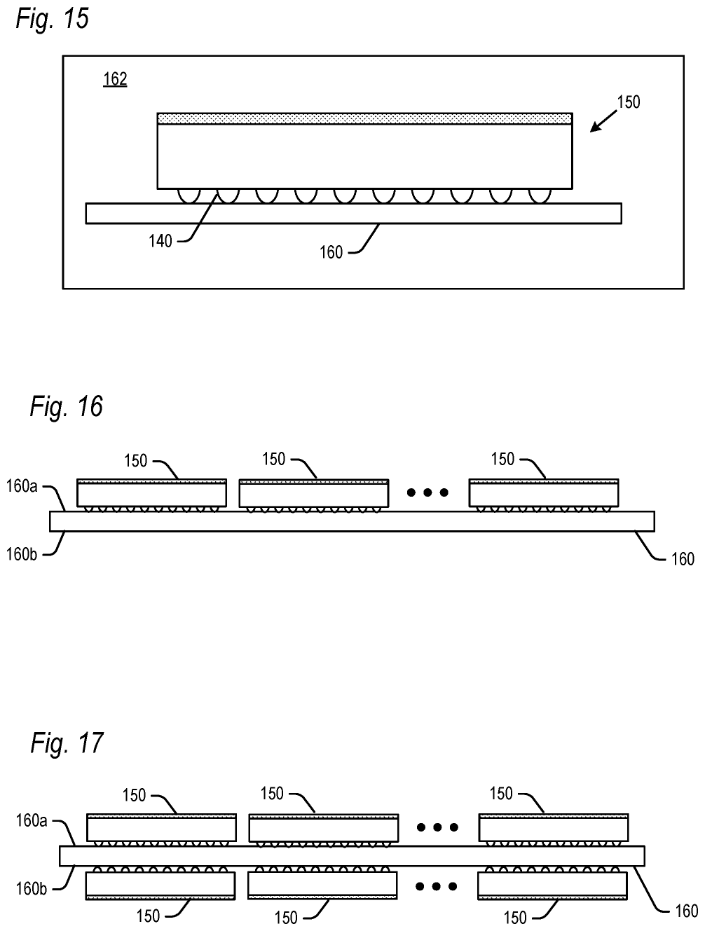

FIG. 15 is a side view of a semiconductor device 150 configured as a BGA package mounted to printed circuit board (PCB) 160 within a host device 162 by solder balls 140. The PCB 160 may have a single semiconductor device 150 as shown in FIG. 15. Alternatively, the PCB 160 may have multiple semiconductor devices 150 mounted thereon as shown in FIGS. 16 and 17. In FIG. 16, the semiconductor devices 150 are mounted to a first surface 160a of the PCB. In FIG. 17, the semiconductor devices 150 are mounted to both of opposed surfaces 160a and 160b of PCB 160. In examples, there may be 2, 4, 8 or 16 semiconductor devices 150 on one or both surfaces 160a, 160b, though there may be other numbers of devices 150 surface 160a and/or 160b. Provision of semiconductor devices 150 on both surfaces of PCB 160 increases the overall memory capacity of the host device 162.

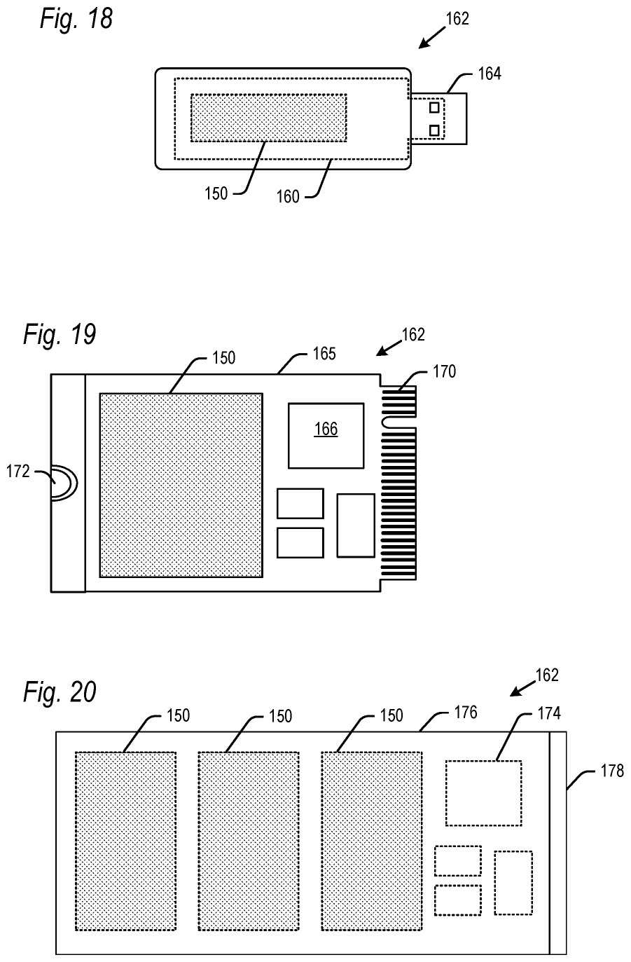

Host device 162 may be any of a wide variety of host devices. FIG. 18 illustrates an example where the host device 162 is a USB device. The USB device 162 includes the PCB 160 and semiconductor device 150 as noted above. The PCB 160 in FIG. 18 may have one or multiple semiconductor devices 150, positioned on one or both sides of PCB 160 as described above. USB device 162 includes an interface connector 164 for plugging into a slot of another device. The interface connector 164 may be formed according to any of the various USB standards.

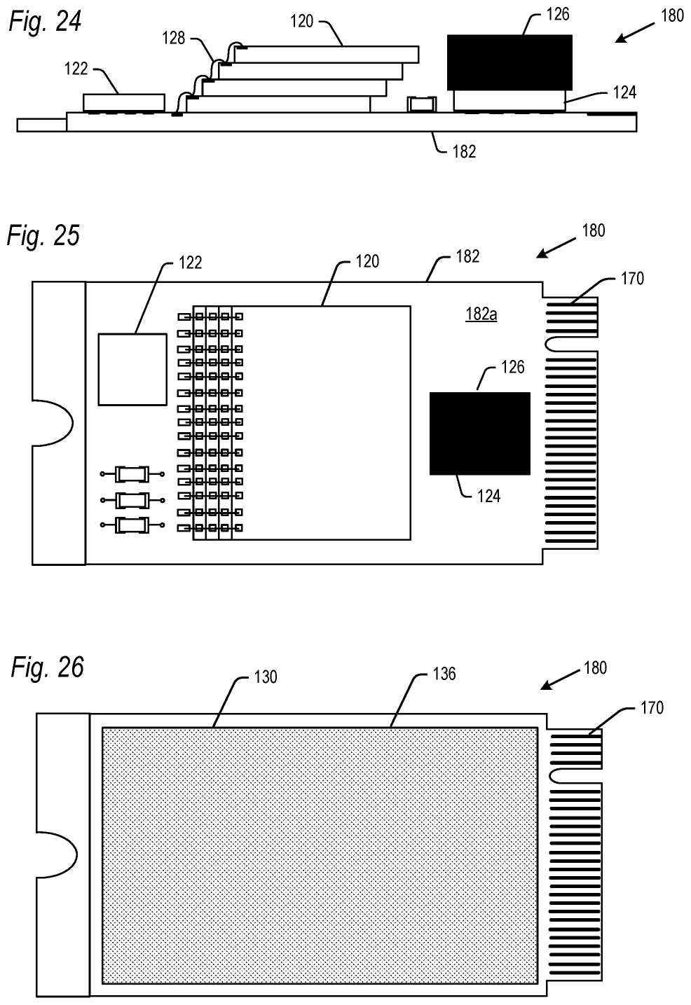

FIG. 19 illustrates an example where the host device 162 is an edge connector card configured to mount to a motherboard of a computing device (not shown). The edge connector card 162 is formed of PCB 165, also referred to herein as an edge connector printed circuit board. A variety of electronic components may be mounted to edge connector PCB 165 including one or more semiconductor devices 150. In further embodiments described below with regard to FIGS. 24-26, flash memory dies 120, controller die 124 and other electronic components may be mounted directly to the edge connector PCB 165 of edge connector card 162 (without substrate 100) and encapsulated in mold compound 130.

In the embodiment of FIG. 19, the one or more semiconductor devices 150 may be mounted on the surface 165a shown in FIG. 19, and/or on the surface 165b, not shown in FIG. 19, opposite surface 165a. One of the other electronic components mounted to edge connector PCB 165 of the edge connector card 162 may be a controller 166. Controller 166 may be used to exchange data and information between the one or more semiconductor devices 150 and the computing device to which the edge connector card 162 is connected. In further embodiments, the controller 166 may integrated into the one or more controller dies 124 (FIG. 10) within the one or more semiconductor devices 150.

The edge connector card 162 may include an edge connector 170 configured to removably fit within an edge connector slot of the host computing device. The edge connector card 162 may further include a thumb grip 172 to facilitate insertion and removal of the edge connector card 162 into and from the edge connector slot. Once mounted in the edge connector slot, data and information may be exchanged between the edge connector card 162 and the host computing device. The edge connector 170 may be configured according to a wide variety of standards.

In embodiments, the edge connector card shown in FIG. 19 may itself be used as an SSD (solid state drive). In further embodiments, multiple edge connector cards as shown in FIG. 19 may be used together as an SSD 162. An SSD 162 may be formed of other components in further embodiments. For example, FIG. 20 is a top view of an SSD 162 having three semiconductor devices 150 mounted to a PCB 160. There may be more or less semiconductor devices 150 in the SSD 162 of FIG. 20 in further examples. SSD 162 may include other electronic components 174 (such as for example a controller) encased within a housing 176, and may have a connector interface 178 for connecting to other devices.

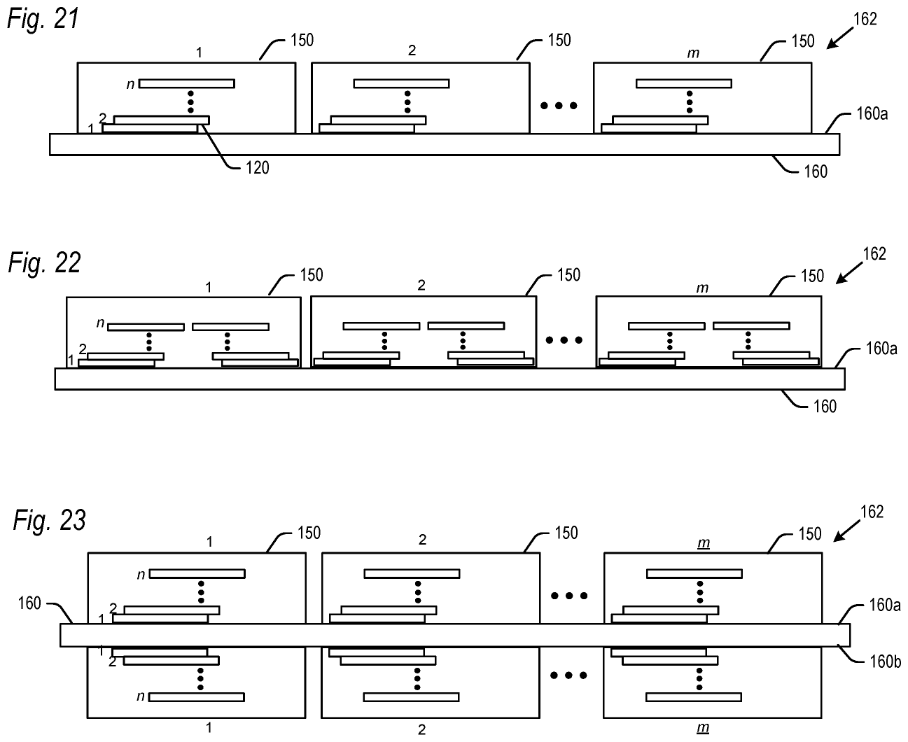

As noted above, it is a feature of the present technology to provide semiconductor devices 150 and host devices 162 with memory capacities which may be customized and scaled as desired for different applications. FIG. 21 is a side view of a host device 162 comprising m number of semiconductor devices 150 mounted on a first surface 160a of a PCB 160. Each semiconductor device may include n number of flash memory dies 120. Each of the semiconductor devices 150 may have the same number or different numbers of semiconductor dies 120. The storage capacity of the device 162 may be tailored and customized to particular applications as needed by varying the number n of semiconductor dies 120 in each semiconductor device 150, and/or by varying the number m of semiconductor devices 150.

The stacking of flash memory dies 120 within semiconductor device 150 may vary in different embodiments, to further enable customized and increased storage capacity to host device 162. FIG. 22 is a side view of an example host device 162 where one or more of the semiconductor devices 150 may have two separate stacks of memory dies 120 to provide a total of 2n dies 120 in each device 150. The stacks may step toward each other as shown, or the stacks may step in the same direction or away from each other. A given host device 162 may include some semiconductor devices 150 having two separate stacks of flash memory dies 120, and others of the semiconductor devices 150 having a single stack of flash memory dies 120.

FIG. 23 shows an embodiment including m number of semiconductor devices 150 on both surfaces 160a and 160b of PCB 160. Each device 150 includes n numbers of flash memory dies 120. Surfaces 160a and 160b may have the same number or different numbers of semiconductor devices 150, and the semiconductor devices 150 may have the same number or different numbers of flash memory dies 120. While a single stack of dies 120 are shown, one or more of the semiconductor devices 150 may have multiple stacks of dies as shown for example in FIG. 22.

Using the semiconductor devices 150 and flash memory dies 120 shown in FIGS. 21-23, or combinations thereof, provides great flexibility and scalability in the storage capacity of the resulting host device 162. In this way, the storage capacity of a host device 162 may be easily customized for particular applications. When placed for example on an edge connector card as shown in FIG. 19, storage capacity may also be increased by increasing the footprint (length and/or width) of the edge connector card to allow space for additional semiconductor devices 150 on a front and/or back side of the edge connector card.

It is a further feature of the present technology that some or all of the semiconductor packages 150 shown in FIGS. 21-23 may include RAM die 122 (FIG. 10). Provision of multiple RAM dies 122 in host device 162 may allow for faster read/write speeds in host device 162 as compared to devices including a single RAM die.

In embodiments described above, finished semiconductor devices 150 (including substrate 100) may be mounted on an edge connector card 162. In further embodiments, substrate 100 may be omitted and the dies and passive components may be mounted directly onto an edge connector PCB 165 to form an SSD edge connector card 180 as shown in FIGS. 24-26. As shown in the side view of FIG. 24 and the top view of FIG. 25, flash memory dies 120, (optionally) RAM die 122 and controller die 124 may be mounted directly onto a surface (e.g., surface 165a) of edge connector PCB 165 of edge connector card 180. The PCB 165 may be same as PCB 165 described above in FIG. 19, including edge connector 170. While four flash memory dies 120 are shown, the edge connector card 180 may have any number and configuration of flash memory dies described above, for example as shown in any of FIGS. 21-23. As noted above, passive components 118 may also be mounted to the PCB 165, and the HSB 126 may be mounted on top of the controller die 124.

Once the dies and components are mounted on PCB 165 and electrically connected as described above, mold compound 130 may be applied over the surface of PCB 165 to encapsulate the dies and passive components. Where the HSB 126 is recessed below the surface of the mold compound, the mold compound above the HSB 126 may then be removed as described above, and the thermally conductive coating 136 may be applied over at least the upper surface of the mold compound 130 as shown in the top view of FIG. 26. As described above, the thermally conductive coating 136 fills in the recess above HSB 126 and lies in contact with an upper surface of the HSB 126 and mold compound 130. The completed edge connector card 180 shown in FIG. 26 may thereafter be plugged into an edge connector slot of a computing device and be used as an SSD device. In further embodiments, it is possible to omit the HSB 126 and thermally conductive coating 136 from the edge connector card shown in FIG. 26.

The edge connector card 180 shown in FIGS. 24-26 provides several advantages. The card 180 may be fabricated using the steps 224-246 of the flowchart of FIG. 1, where the PCB 165 is substituted for the substrate 100 and substrate panel 102. Omission of the substrate 100 results in a savings in material and a reduction in assembly steps. Similarly, as there is no panel of substrates, there is no need to singulate the finished molded packages from the panel. Moreover, solder balls may be affixed to a bottom surface of conventional semiconductor packages, which solder balls are later used to affix the conventional semiconductor packages to a PCB such as PCB 160. In the embodiment of FIGS. 24-26, the dies and components are surface mounted directly to the PCB 165, and solder balls may be omitted, resulting in a savings in material and a reduction in assembly steps.

Furthermore, during assembly of conventional semiconductor packages, there are several process and inspection steps performed on the substrate, individual semiconductor dies and the finished package. In the edge connector card 180, several of these process and inspection steps may be simplified and/or omitted altogether. For example, there are inspection steps associated with inspection of the substrate, and formation of the solder balls on the bottom surface of the substrate. Again, as there are no substrate or solder balls, the inspection and process steps associated with the substrate and solder balls may be omitted, including the step of underfilling the space on a bottom surface of the substrate around the solder balls. Moreover, there are several inspection steps and process steps in preparing conventional packages to be shipped for bonding the solder balls to a PCB. In this embodiment, these inspection and process steps may be omitted.

The edge connector card 180 of FIGS. 24-26 further provides advantages with respect to simplified testing of the edge connector card and its components. Conventionally, testing was done on the dies, electrical connections and other components once each was mounted on the substrate. Thereafter, the finished semiconductor device was again tested, and tested yet again once mounted to a PCB. Here, the components only need be tested after they are all mounted on PCB 165. Moreover, the bottom surface 165b of PCB 165 (opposed to surface 165a shown in FIG. 25) may include a pattern of test pins, such as test pins 114 shown in FIGS. 4A and 4B. These test pads 114 on the bottom surface 165b may be accessed by test pins to enable testing of all dies and possibly other electronic components on the PCB 165, from the bottom of the PCB 165. This is an improvement over conventional test processes, where the edge connector of each edge connector card with memory dies is plugged into a dedicated test socket.

As will be understood from the above description, the term “solid state drive” or “SSD” as used herein is intended to cover any of a wide variety of memory devices or host devices, which in general are assembled without certain moving parts conventionally found in a rotating disk drive. In one embodiment, the semiconductor device 150 (e.g., FIGS. 11 and 12) is an example of a solid state drive. In a further example, a host device including one or more semiconductor devices 150 mounted to a PCB 160 (e.g., FIGS. 19 and 20) is an example of a solid state drive. In another example, one or more memory dies, a controller die and other components mounted directly to the surface of an edge connector PCB 165 (e.g., FIGS. 24-26) is an example of a solid state drive.

In summary, in one example, the present technology relates to a solid state drive, comprising: a chip carrier medium; one or more semiconductor memory dies mounted to the chip carrier medium; a semiconductor controller die having a first surface and a second surface, the first surface of the semiconductor controller die mounted to the chip carrier medium; a heat spreader block having a third surface and a fourth surface, the third surface of the heat spreader block mounted on the second surface of the semiconductor controller die, the heat spreader block configured to remove heat from the semiconductor controller die; an enclosure around at least the one or more semiconductor memory dies and the semiconductor controller die, the fourth surface of the heat spreader block exposed at a surface of the enclosure; and a thermally conductive film on a surface of the enclosure and in contact with the fourth surface of the heat spreader block, the thermally conductive film on the surface of the enclosure configured to remove heat from the heat spreader block.

In another example, the present technology relates to a solid state drive, comprising: an edge connector printed circuit board, the edge connector printed circuit board comprising an edge connector configured to mate within an edge connector socket; one or more semiconductor memory dies surface mounted directly to the edge connector printed circuit board; a semiconductor controller die surface mounted directly to the edge connector printed circuit board; and an enclosure affixed to the edge connector printed circuit board and encasing the one or more semiconductor memory dies and the semiconductor controller die.

In a further example, the present technology relates to a solid state drive, comprising: a chip carrier medium; one or more semiconductor memory dies mounted to the chip carrier medium; a semiconductor controller die having a first surface and a second surface, the first surface of the semiconductor controller die mounted to the chip carrier medium; block means for conducting heat away from the semiconductor controller die; an enclosure around at least the one or more semiconductor memory dies the semiconductor controller die, and at least part of the block means; and film means around at least part of the enclosure and in communication with the block means, the film means for conducting heat away from the block means to an environment surround the solid state drive.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A solid state drive, comprising:
a chip carrier medium;
one or more semiconductor memory dies mounted to the chip carrier medium;
a semiconductor controller die having a first surface and a second surface, the first surface of the semiconductor controller die mounted to the chip carrier medium;
a heat spreader block having a third surface and a fourth surface, the third surface of the heat spreader block mounted on the second surface of the semiconductor controller die, the heat spreader block configured to remove heat from the semiconductor controller die;
an enclosure around at least the one or more semiconductor memory dies and the semiconductor controller die, the fourth surface of the heat spreader block exposed at a surface of the enclosure; and
a thermally conductive film on a surface of the enclosure and in contact with the fourth surface of the heat spreader block, the thermally conductive film on the surface of the enclosure configured to remove heat from the heat spreader block.

2. The solid state drive of claim 1, wherein the chip carrier medium is a substrate.

3. The solid state drive of claim 1, wherein the chip carrier medium is a printed circuit board.

4. The solid state drive of claim 3, wherein the one or more semiconductor memory dies and the controller die are mounted directly to a surface of the printed circuit board.

5. The solid state drive of claim 1, further comprising a printed circuit board, wherein the chip carrier medium is a substrate and wherein the one or more semiconductor memory dies and the controller die are mounted directly to a first surface of the substrate, and a second surface of the substrate opposed to the first surface of the substrate is mounted directly to the printed circuit board.

6. The solid state drive of claim 5, wherein the one or more semiconductor memory dies are stacked one upon another.

7. The solid state drive of claim 1, wherein the surface of the enclosure comprises a planar surface, and wherein the fourth surface of the heat spreader block resides within a recess formed into the planar surface and wherein the thermally conductive film resides within the recess, against the fourth surface of the heat spreader block.

8. The solid state drive of claim 1, wherein the thermally conductive film is also electrically conductive to absorb and/or shield the solid state drive against electromagnetic interference.

9. The solid state drive of claim 1, wherein the enclosure further includes sides extending at angles from the surface of the enclosure, and wherein the thermally conductive film is further provided on one or more of the sides.

10. The solid state drive of claim 1, wherein the chip carrier medium comprises first and second sides, and
wherein the one or more semiconductor memory dies comprise a first group of one or more semiconductor memory dies mounted to the first side of the chip carrier medium,
wherein the semiconductor controller die comprises a first semiconductor controller die mounted to the first side of the chip carrier medium, and
wherein the enclosure comprises a first enclosure affixed to the first side of the chip carrier medium;
the solid state drive further comprising:
a second group of one or more semiconductor memory dies mounted to the second side of the chip carrier medium;
a second semiconductor controller die mounted to the second side of the chip carrier medium; and
a second enclosure attached to the second side of the chip carrier medium, the second enclosure encasing at least the second group of one or more semiconductor memory dies and the second semiconductor controller die.

11. The solid state drive of claim 1, wherein the chip carrier medium comprises first and second sides, and
wherein the one or more semiconductor memory dies comprise a first group of one or more semiconductor memory dies mounted to the first side of the chip carrier medium,
wherein the semiconductor controller die comprises a first semiconductor controller die mounted to the first side of the chip carrier medium, and
wherein the enclosure comprises a first enclosure affixed to the first side of the chip carrier medium;
the solid state drive further comprising:
a second group of one or more semiconductor memory dies mounted to the first side of the chip carrier medium;
a second semiconductor controller die mounted to the first side of the chip carrier medium; and
a second enclosure attached to the first side of the chip carrier medium, the second enclosure encasing at least the second group of one or more semiconductor memory dies and the second semiconductor controller die.

12. The solid state drive of claim 1, wherein the chip carrier medium includes contact fingers, and the solid state drive is configured as a memory card.

13. The solid state drive of claim 1, wherein the chip carrier medium includes solder balls, and the solid state drive is configured as one of a USB device and an edge connector card.

14. A solid state drive, comprising:
an edge connector printed circuit board, the edge connector printed circuit board comprising an edge connector configured to mate within an edge connector socket;
one or more semiconductor memory dies surface mounted directly to the edge connector printed circuit board;
a semiconductor controller die surface mounted directly to the edge connector printed circuit board; and
an enclosure affixed to the edge connector printed circuit board and encasing the one or more semiconductor memory dies and the semiconductor controller die.

15. The solid state drive of claim 14, wherein the semiconductor controller die comprises a first surface and a second surface, the first surface of the semiconductor controller die being directly mounted to the edge connector printed circuit board, the solid state drive further comprising:
a heat spreader block having a third surface and a fourth surface, the third surface of the heat spreader block mounted on the second surface of the semiconductor controller die, the heat spreader block configured to remove heat from the semiconductor controller die, the fourth surface of the heat spreader block exposed at a surface of the enclosure; and
a thermally conductive film on a surface of the enclosure and in contact with the fourth surface of the heat spreader block, the thermally conductive film on the surface of the enclosure configured to remove heat from the heat spreader block.

16. The solid state drive of claim 15, wherein the surface of the enclosure comprises a planar surface, and wherein the fourth surface of the heat spreader block resides within a recess formed into the planar surface, and wherein the thermally conductive film resides within the recess, against the fourth surface of the heat spreader block.

17. The solid state drive of claim 15, wherein the thermally conductive film is also electrically conductive to absorb and/or shield the solid state drive against electromagnetic interference.

18. The solid state drive of claim 14, wherein the edge connector printed circuit board comprises a first side and a second side opposed to the first side, and wherein the one or more semiconductor memory dies and the controller die are mounted to the first side of the edge connector printed circuit board, the solid state drive further comprising test pads exposed on the second surface of the edge connector printed circuit board, the test pads configured to receive test pins to test operation of the solid state drive.

19. The solid state drive of claim 14, wherein the one or more semiconductor memory dies comprise one or more flash memory dies and a random access memory die.

20. A solid state drive, comprising:
a chip carrier medium;
one or more semiconductor memory dies mounted to the chip carrier medium;
a semiconductor controller die having a first surface and a second surface, the first surface of the semiconductor controller die mounted to the chip carrier medium;
block means for conducting heat away from the semiconductor controller die;
an enclosure around at least the one or more semiconductor memory dies, the semiconductor controller die, and at least part of the block means; and
film means around at least part of the enclosure and in communication with the block means, the film means for conducting heat away from the block means to an environment surround the solid state drive.
